(19) United States
(12) Patent Application Publication
(10) Pub. No.: US 2002/0080593 A1
(43) Pub. Date: Jun. 27, 2002

(54) Shield case, manufacturing method therefor, and electronic device

(75) Inventors: Shusaku Tsuge, Sagamihara-shi (JP); Shigeru Suzuki, Niiza-shi (JP); Hirokazu Kageyama, Tachikawa-shi (JP)

Correspondence Address: Finnegan, Henderson, Farabow, Garrett & Dunner, L.L.P., 1300 I Street N.W., Washington, DC, 20005-3315, US

(73) Assignee: KABUSHIKI KAISHA TOSHIBA

(21) Appl. No.: 10/015,590

(22) Filed: Dec. 17, 2001

(30) Foreign Application Priority Data
Dec. 21, 2000 (JP) 2000-388160
Dec. 12, 2001 (JP) 2001-378673

(51) Int. Cl. H05K 9/00

(52) U.S. Cl. 361/818

(57) ABSTRACT

An electronic device includes a circuit board on which an electronic component is mounted and a ground pattern surrounding the electronic component is formed, a shield case which is formed by drawing a mesh material formed by weaving a conductive wire, stores the electronic component, and has a box-like room with a peripheral portion for ground around an open end, and a housing which incorporates the circuit board and shield case and has a rib formed at a predetermined position on the inner surface in order to bring the peripheral portion into press contact with the ground pattern.

### CROSS-REFERENCE TO RELATED APPLICATIONS

This application is based upon and claims the benefit of priority from the prior Japanese Patent Applications No. 2000-388160, filed Dec. 21, 2000; and No. 2001-378673, filed Dec. 12, 2001, the entire contents of both of which are incorporated herein by reference.

### BACKGROUND OF THE INVENTION

1. Field of the Invention

The present invention relates to a shield case for preventing radio interference between elements and circuits of an electronic device, radio incidence on the device, and radio emission from the device, a method of manufacturing the shield case, and an electronic device in which the shield case is mounted.

2. Description of the Related Art

In general, an RF (radio frequency) electronic device such as a portable telephone is provided with an RF shield in order to mainly prevent radio interference between modules and external radio emission. FIG. 1 shows an example of an RF shield. A shield case 6 is attached to a circuit board 2 so as to cover an electronic component 4 in order to shield the electronic component 4 mounted on the circuit board 2 from RF waves. The shield case 6 comprises a top plate 8 and four side plates 10, and has a box-like outer appearance with an open surface (bottom surface). The material of the shield case 6 is a resin material or metal plate (metal).

FIG. 2 shows the cross section of a shield case 6A made of a resin material. The surfaces of the top plate 8 and side plates 10 of the shield case 6A are coated with a plating layer 12 made of a conductive metal. A ground pattern 16 surrounding the electronic component 4 is formed on the surface of a base 14 of the circuit board 2 which supports the electronic component 4. When the shield case 6A is mounted at a predetermined position of the circuit board 2 so as to cover the electronic component 4, the plating layer 12 at the open edges of the side plates 10 of the shield case 6A contacts the ground pattern 16. In this manner, the shield case 6A is rendered conductive to shield the electronic component 4 from RF waves.

However, if the shield case 6A is made from a resin material, a gap may be formed between the ground pattern 16 of the circuit board 2 and the plating layer 12 at the open edges of the side plates 10 of the shield case 6A due to deformation (distortion) of the shield case 6A or deformation (corrugation) of the circuit board 2. In this case, the plating layer 12 and ground pattern 16 cannot be in satisfactory contact with each other, and desired shielding performance cannot be manufactured, degrading radio performance.

To prevent this, when the shield case 6A is made from a resin material, an conductive elastic member 18 such as a conductive rubber or conductive spring with both elasticity and conductivity is applied to the open ends of the side plates 10 of the shield case 6A, as shown in FIG. 3. The conductive elastic member 18 can achieve secure contact between the ground pattern 16 of the circuit board 2 and the plating layer 12 at the open edges of the side plates 10 of the shield case 6A even upon deformation of the shield case 6A or circuit board 2.

In the above arrangement, however, the conductive elastic member 18 such as a conductive rubber or conductive spring must be aligned to the open edge of the shield case 6A in mounting the shield case 6A on the circuit board 2. This complicates the mounting process of the shield case 6A. Since the resin material is plated with the conductive material, the plating layer is difficult to remove from the resin material in disposal, which makes recycling difficult.

FIG. 4 shows the cross section of a shield case 6B made of a metal plate. The open edges of the side plates 10 of the shield case 6B are attached to the ground pattern 16 of the circuit board 2 via solder 20.

The solder 20 can achieve secure contact between the open edges and the ground pattern 16 even upon deformation of the shield case 6B or circuit board 2. In this case, however, the metal plate shield case 6B is difficult to dismount from the circuit board 2 in disposal, which also makes recycling difficult. The box-like case is manufactured by processing a flat metal plate (pressing), so a shield case of a complicated shape cannot be pressed.

A conventional shield case made of a resin material suffers the following problem. That is, a gap is formed between the ground pattern of the circuit board and the plating layer at the open edges of the side plates of the shield case owing to deformation of the shield case or board. At the gap portion, the ground pattern and plating layer cannot satisfactorily contact each other. Desired shielding performance cannot be manufactured, degrading radio performance. A solution to this problem may complicate the mounting process of the shield case, as shown in FIG. 2.

In a shield case made from a metal plate, soldering achieves secure contact between the open edges of the side plates of the metal plate shield case and the ground pattern of the circuit board. However, the shield case is difficult to dismount from the circuit board. Since a flat metal plate is processed, a case of a complicated shape cannot be pressed. Further, either a resin material or metal plate used as the shield case material makes recycling difficult.

### BRIEF SUMMARY OF THE INVENTION

It is an object of the present invention to provide a shield case which is easily mounted/dismounted, obtains desired shielding performance, and is easily manufactured, a method of manufacturing the shield case, and an electronic device in which the shield case is mounted.

According to an embodiment of the present invention, a shield case is made from a mesh material formed by weaving a conductive wire, has a box-like shape with an open surface, and has a peripheral portion for ground at an open end of the box.

A shield case according to another embodiment is made from a mesh material formed by weaving a conductive wire, has a plurality of box-like rooms each with an open surface, and has a peripheral portion for ground at an open end of each box.

The shield case according to the above embodiments is elastic because the mesh material is used. The shield case is therefore reliably grounded without using any elastic member or solder, unlike the prior art.

In the shield case according to a still another embodiment, an end of the conductive wire of the mesh material is rounded. Thus, the shield case need not be carefully handled by hands or the like.

In the shield case according to a still further embodiment, a mesh of the conductive wire of the mesh material crosses a fold of the box. A mesh of the conductive wire of the mesh material preferably crosses a fold of the box at 45°. Not only the conductive wire stretches in forming into a box shape, but also the mesh shape is widened. Hence, the conductive wire is not cut.

According to still another embodiment, there is provided a shield case manufacturing method of drawing a mesh material formed by weaving a conductive wire, forming a box-like room with an open surface, and forming a peripheral portion for ground at an open end of the box.

According to still further embodiment, there is provided a shield case manufacturing method of interposing a mesh material formed by weaving a conductive wire between convex and concave molds to draw the mesh material, forming a plurality of box-like rooms each with an open surface, and forming a peripheral portion for ground at an open end of each box.

Since the shield case manufacturing method according to the still another embodiment and still further embodiment uses the mesh material, a case of an arbitrary shape is easily manufactured.

An electronic device according to still another embodiment comprises a circuit board on which an electronic component is mounted and a ground pattern surrounding the electronic component is formed, a shield case which has a room for storing the electronic component, has a peripheral portion formed around an open surface of the room, and is made from a mesh material formed by weaving a conductive wire, and a housing which incorporates the circuit board and the shield case and has a projection formed at a predetermined position on an inner surface in order to bring the peripheral portion into press contact with the ground pattern.

In the electronic device according to the still another embodiment, the shield case is reliably brought into contact with the ground pattern of the circuit board without using any elastic member or solder. The shield case is easily be mounted/dismounted.

### BRIEF DESCRIPTION OF THE SEVERAL VIEWS OF THE DRAWING

The accompanying drawings, which are incorporated in and constitute a part of the specification, illustrate embodiments of the present invention and, together with the general description given above and the detailed description of the embodiments given below, serve to explain the principles of the present invention in which:

FIG. 1 is a perspective view showing a conventional shield case together with a circuit board;

FIG. 2 is a sectional view showing an example of a state wherein a conventional shield case using a resin material is mounted on the circuit board;

FIG. 3 is a sectional view showing another example of the state wherein the conventional shield case using a resin material is mounted on the circuit board;

FIG. 4 is a sectional view showing an example of a state wherein a conventional shield case using a metal plate is mounted on a circuit board;

FIG. 5 is a perspective view showing the arrangement of a shield case according to an embodiment of the present invention;

FIG. 6 is a plan view showing the shield case according to the embodiment of the present invention;

FIGS. 7A and 7B are views for explaining a method of fabricating the shield case according to the embodiment of the present invention by drawing;

FIG. 8 is a perspective view for explaining thermal cutting of an unnecessary end by a laser in fabricating the shield case according to the embodiment of the present invention;

FIG. 9A is a view showing the cut portion of a wire in the shield case by pressing;

FIG. 9B is a view showing the cut portion of a wire in the shield case according to the embodiment of the present invention;

FIGS. 10A, 10B, and 10C are views for explaining the effect of forming while tilting the weaving direction of a mesh material from the drawing direction in the shield case according to the embodiment of the present invention;

FIG. 11 is an exploded perspective view showing the structure of a portable telephone which incorporates the shield case according to the embodiment of the present invention; and

FIG. 12 is a sectional view showing the detailed structure of the major portion of the portable telephone shown in FIG. 11.

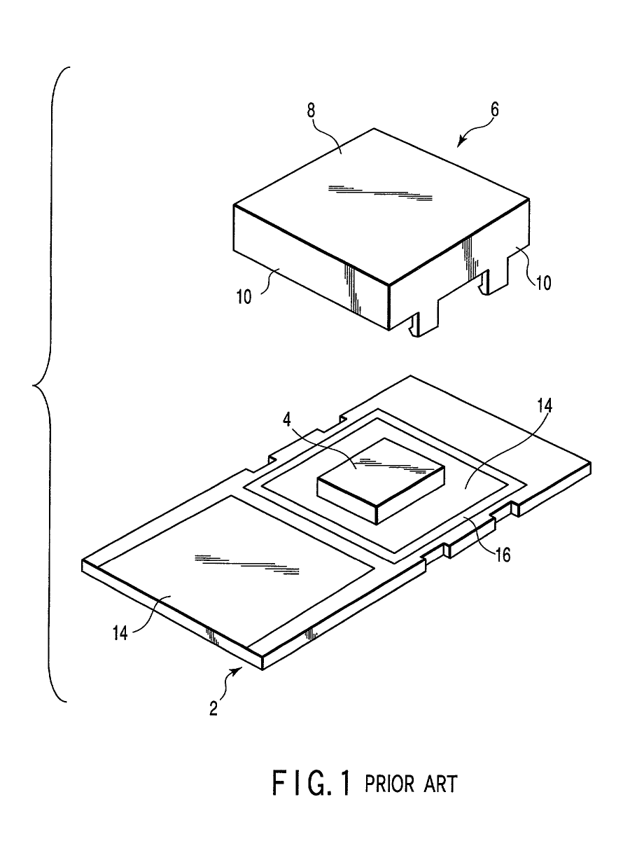

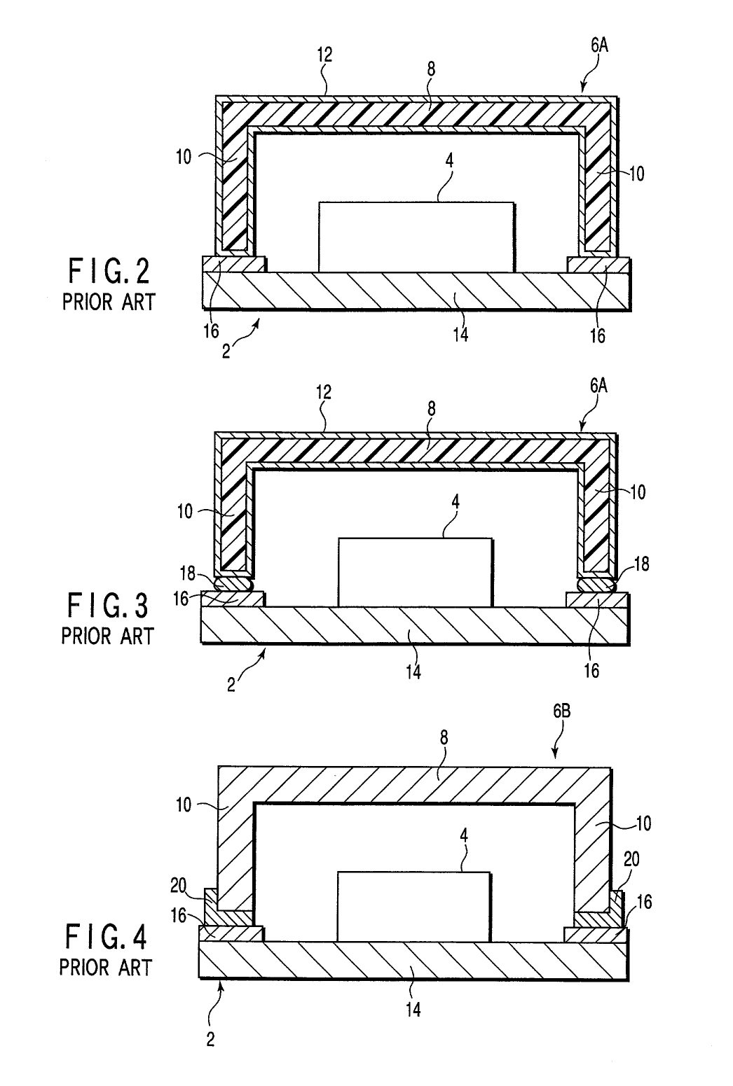

### DETAILED DESCRIPTION OF THE INVENTION

An embodiment of a shield case according to the present invention will now be described with reference to the accompanying drawings.

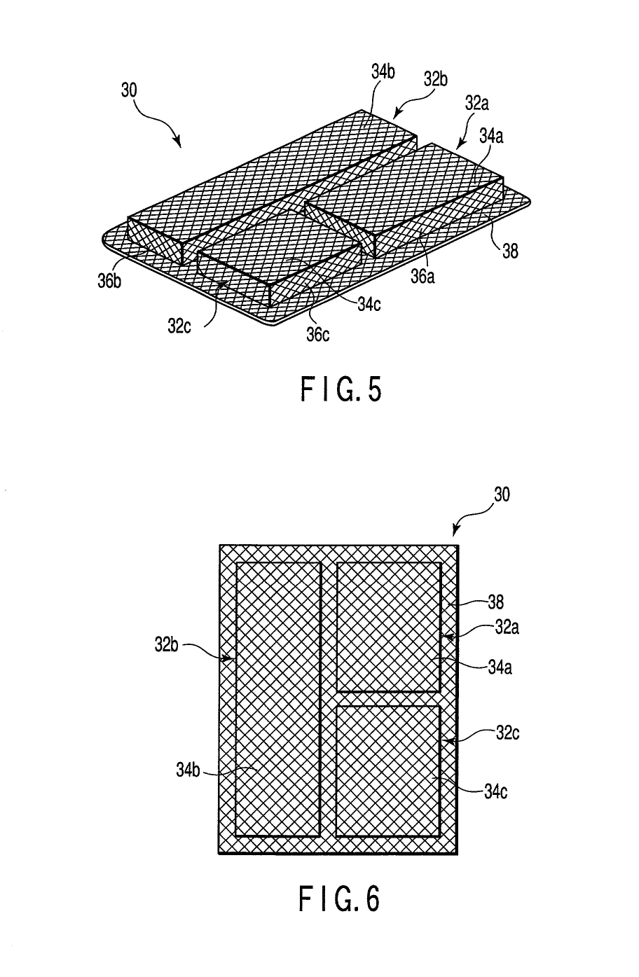

FIG. 5 is a perspective view showing the outer appearance of a shield case according to the embodiment of the present invention. FIG. 6 is a plan view of the shield case. A shield case 30 is divided into rooms for respective electronic components which must be shielded. In this embodiment, the shield case 30 has three rooms 32a, 32b, and 32c. The rooms 32a, 32b, and 32c have top plates 34a, 34b, and 34c, and side plates 36a, 36b, and 36c, respectively. A peripheral portion 38 is formed around the open edges of the side plates 36a, 36b, and 36c of the rooms 32a, 32b, and 32c.

The material of the shield case 30 is not a metal plate but a conductive wire such as a mesh material formed by weaving a steel wire. The mesh material can attain a satisfactory shield effect as far as the mesh size is 1/100 or less of the wavelength. The shield case 30 is manufactured by drawing the mesh material.

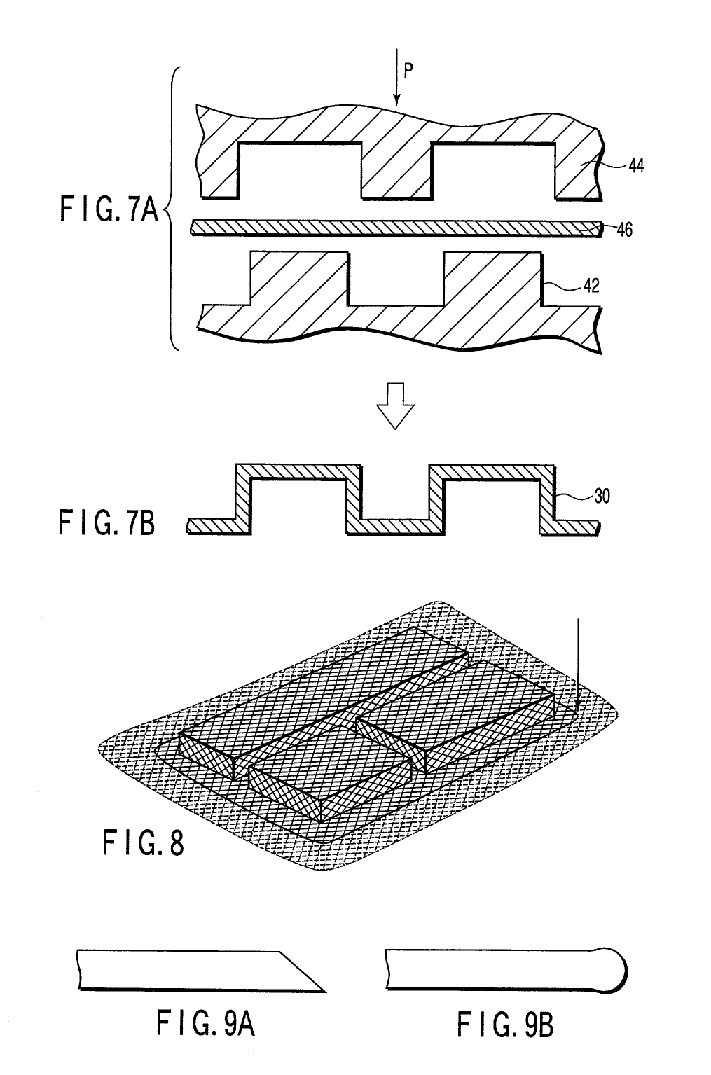

FIGS. 7A and 7B are views for explaining a method of fabricating the shield case 30 by drawing. As shown in FIG. 7A, a punch 42 and die 44 corresponding to the shapes of the rooms 32a, 32b, and 32c of the shield case 30 are prepared. A flat mesh material 46 is interposed between the punch 42 and die 44, drawn several times under a pressure P, and removed from the punch 42 and die 44. The shield case 30 is manufactured from the mesh material 46 deformed as shown in FIG. 7B.

The mesh material 46 is larger than the shield case, and an unnecessary end (broken line in FIG. 8) is cut off after drawing. In a shield case manufactured by pressing of a metal plate described in the prior art, the end is cut off by pressing. If the same cutting is done for the shield case of this embodiment, the cut portion becomes sharp, as shown in FIG. 9A, because the wires of the mesh material are extracted one by one. Such a shield case is difficult to manually handle. To prevent this, an unnecessary end is thermally cut by a laser in the embodiment. In this case, the end of the mesh wire can be rounded, as shown in FIG. 9B. The shield case need not be carefully handled by hands or the like.

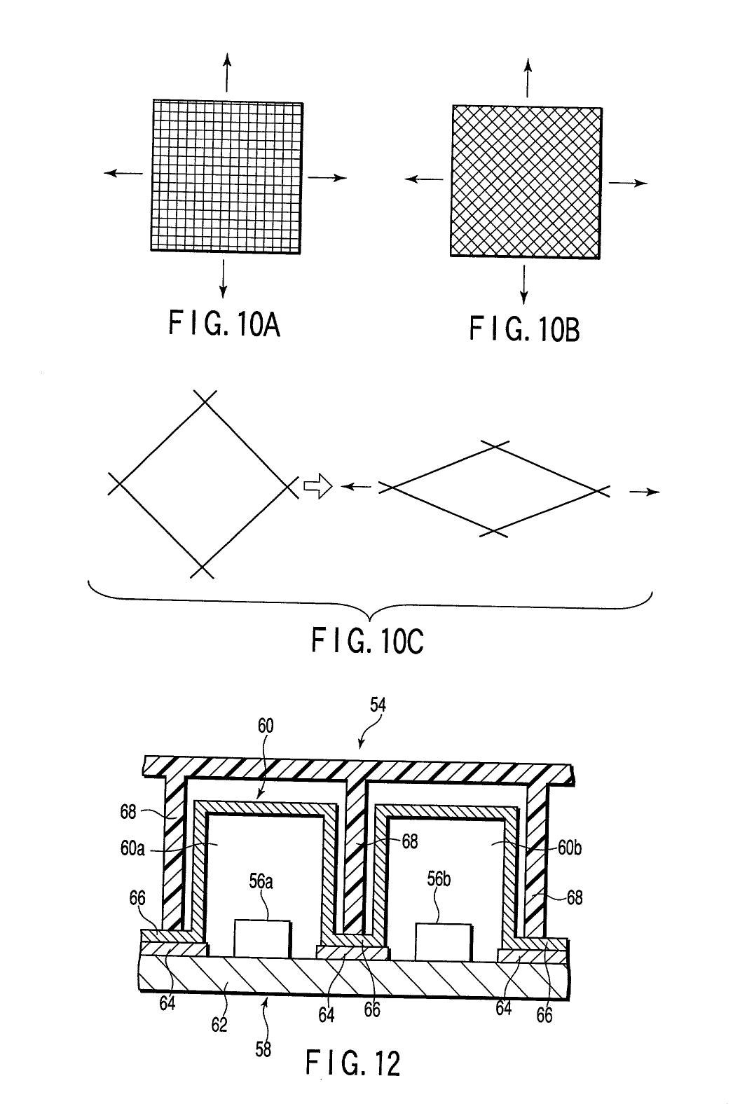

Since the material stretches by drawing, a metal plate may be worn out at a drawn portion if it is used as the material. To the contrary, a mesh material resistant to drawing is hardly worn out. The strength of the mesh material is increased by devising the mesh layout. Drawing is performed by laying out the mesh material such that the weaving direction of the mesh material, i.e., the direction of a steel wire is tilted by 45° from each side of a rectangle forming the outer shape of the rectangular top plate 34a, 34b, or 34c, as shown in FIGS. 5 and 6. FIGS. 10A, 10B, and 10C are views for explaining the effect of laying out the mesh material in this direction and drawing it. When the steel wire direction is set parallel to each side of the rectangle forming the outer shape of the top plate 34a, 34b, or 34c, the steel wire direction coincides at a drawn portion with the direction of each side of the rectangle forming the outer shape of the top plate 34a, 34b, or 34c, as shown in FIG. 10A. Thus, drawing is done mainly by stretch of the steel wire, and the steel wire may be cut by drawing. To prevent this, the steel wire direction is tilted by 45° from each side of the rectangle forming the outer shape of the top plate 34a, 34b, or 34c, and drawing is performed in a direction tilted by 45° from the steel wire direction, as shown in FIG. 10B. Hence, not only the steel wire stretches, but also the mesh shape is widened, as shown in FIG. 10C. The shape as shown in FIG. 5 can be realized without cutting the steel wire. The tilt angle of the steel wire from each side of the rectangle forming the outer shape of the top plate 34a, 34b, or 34c is not limited to 45°. By tilting the steel wire direction by another arbitrary angle, the mesh shape can be widened to a certain degree.

In this way, the shield case 30 is manufactured using a mesh material by drawing. Compared to pressing a metal plate, a shield case of a complicated shape can easily be formed. The peripheral portion 38 can be made elastic by using a mesh material formed by weaving a steel wire as the material of the shield case 30. The shield case 30 can be reliably brought into contact with the ground pattern of the circuit board without attaching the shield case to the circuit board via another conductive elastic member, unlike the use of a resin material described in the prior art. The shield case 30 can easily be mounted.

Further, the shield case 30 can easily be dismounted because it need not be soldered, unlike the use of a metal plate described in the prior art. Since the shield case 30 is easily dismounted and made of a single material, it can easily be recycled.

In addition, the shield case becomes lighter than a shield case made from a flat plate by using the mesh material formed by weaving a steel wire as the material of the shield case 30. Note that the material of the shield case 30 is not limited to the mesh material formed by weaving a steel wire, but can be a mesh material formed by weaving another conductive wire, e.g., a wire of copper, nickel, or aluminum.

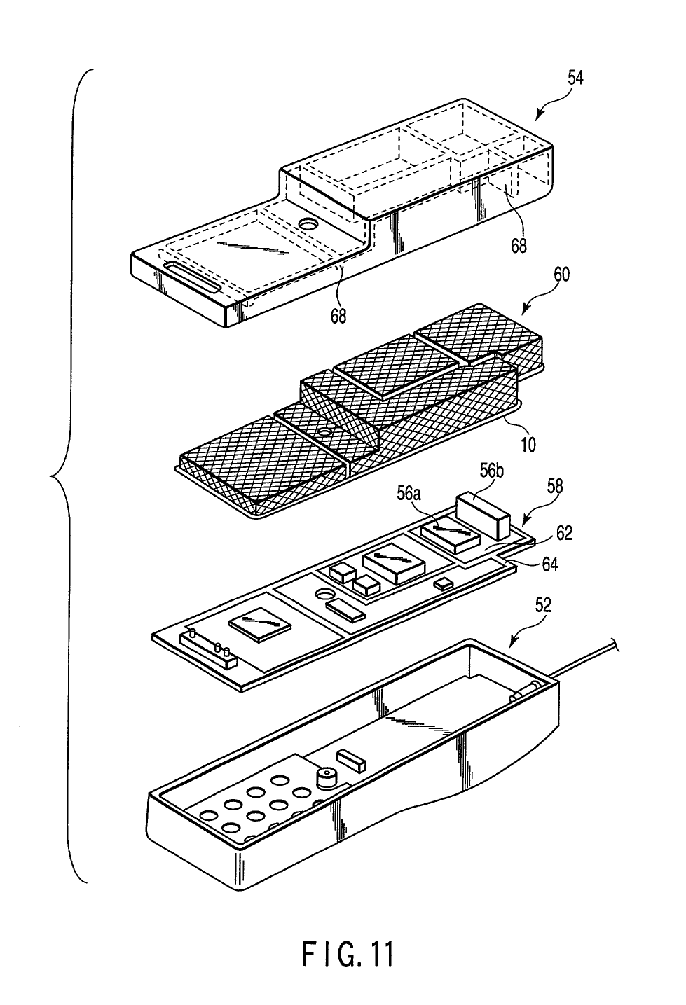

FIGS. 11 and 12 show the structure of a portable telephone in which the shield case according to the embodiment of the present invention is assembled. FIG. 11 is an exploded perspective view showing the portable telephone, and FIG. 12 is a sectional view showing the detailed structure of the main part. As shown in FIG. 11, the portable telephone comprises upper and lower cases (housings) 52 and 54 made of a plastic, a circuit board 58 which is stored in the upper and lower cases (housings) 52 and 54 and supports electronic components 56a and 56b, and a shield case 60.

As shown in FIGS. 11 and 12, the surface of a base 62 of the circuit board 58 bears a wiring pattern (not shown) which connects the mounted electronic components 56a and 56b, and bears a ground pattern 64 surrounding the electronic components 56a and 56b.

As shown in FIG. 12, the shield case 60 has rooms 60a and 60b for incorporating the electronic components 56a and 56b. A peripheral portion 66 is formed around the open surfaces of the rooms 60a and 60b. Ribs (projections) 68 for pressing the peripheral portion 66 are formed on the lower case 54 at positions corresponding to the peripheral portion 66 formed around the open surfaces of the rooms 60a and 60b of the shield case 60. The shield case 60 is so mounted as to cover the electronic components 56a and 56b on the circuit board 58. The shield case 60 is brought into contact with the ground pattern 64 of the circuit board 58 by pressing the peripheral portion 66 of the shield case 60 by the ribs (projections) 68 of the lower case 54. This structure can attain secure contact between the shield case 60 and the ground pattern 64 of the circuit board 58 and can realize RF shielding.

The ground pattern 64 formed on the circuit board 58 need not always be formed at all positions where the ground pattern 64 surrounds the mounted electronic components 56a and 56b. A ground pattern between adjacent electronic components may be properly omitted as far as the ground pattern is formed on at least the outermost position where the ground pattern surrounds all the electronic components 56a and 56b.

As has been described above, according to the embodiment, a mesh material formed by weaving a conductive wire is adopted as the material of a shield case assembled into an electronic device. The shield case becomes lighter than a shield case made from a flat plate. The shield case can easily be mounted/dismounted on/from the circuit board, and can easily be recycled.

While the description above refers to particular embodiments of the present invention, it will be understood that many modifications may be made without departing from the spirit thereof. The accompanying claims are intended to cover such modifications as would fall within the true scope and spirit of the present invention. The presently disclosed embodiments are therefore to be considered in all respects as illustrative and not restrictive, the scope of the invention being indicated by the appended claims, rather than the foregoing description, and all changes that come within the meaning and range of equivalency of the claims are therefore intended to be embraced therein. For example, a shield case made up of a plurality of rooms has been exemplified in the above description, but the shield case may be comprised of only a room. A portable telephone has been exemplified as an electronic device, but the electronic device is not limited to this as far as it requires RF shielding.

What is claimed is:

1. A shield case comprises:
a mesh material formed by weaving a conductive wire and having a box-like shape portion with an open surface; and
a peripheral portion for ground provided at an open end of the box-like portion.

2. The shield case according to claim 1, wherein said mesh material has a plurality of box-like rooms each with an open surface, and the peripheral portion for ground is formed at an open end of each box.

3. The shield case according to claim 1, wherein an end of the conductive wire of the mesh material is rounded.

4. The shield case according to claim 1, wherein the box-like shape portion is manufactured by drawing the mesh material.

5. The shield case according to claim 1, wherein a mesh of the conductive wire of the mesh material crosses a fold of the box-like portion.

6. A shield case manufacturing method comprising:
drawing a mesh material formed by weaving a conductive wire;
forming a box-like room with an open surface; and
forming a peripheral portion for ground at an open end of the box-like room.

7. The shield case manufacturing method according to claim 6, wherein drawing the mesh material comprises interposing the mesh material between convex and concave molds, forming the box-like room comprises forming a plurality of box-like rooms each with an open surface, and forming the peripheral portion comprises forming the peripheral portion at an open end of each box.

8. The method according to claim 6, further comprising thermally cutting an end of the conductive wire of the mesh material by laser after drawing.

9. The method according to claim 6, wherein drawing the mesh material comprises drawing the mesh material so as to make a mesh of the conductive wire cross a fold of the box-like room.

10. An electronic device comprising:
a board on which an electronic component is mounted and a ground pattern surrounding the electronic component is formed;
a shield case including a box-like room for storing the electronic component and a peripheral portion formed around an open surface of the room, the shield case being made from a mesh material formed by weaving a conductive wire; and
a housing which incorporates said board and said shield case and has a projection formed at a predetermined position on an inner surface in order to bring the peripheral portion into press contact with the ground pattern.

11. The electronic device according to claim 10, wherein an end of the conductive wire of the mesh material is rounded.

12. The electronic device according to claim 10, wherein the box-like room of the shield case is manufactured by drawing the mesh material.

13. The electronic device according to claim 10, wherein a mesh of the conductive wire of the mesh material crosses a fold of the box-like room.
